(19) United States
(12) Patent Application Publication
(10) Pub. No.: US 2015/0225871 A1
(43) Pub. Date: Aug. 13, 2015

(54) SiC SINGLE CRYSTAL PRODUCTION APPARATUS AND METHOD OF PRODUCING SiC SINGLE CRYSTALS

(71) Applicants: NIPPON STEEL & SUMITOMO METAL CORPORATION, Tokyo (JP); TOYOTA JIDOSHA KABUSHIKI KAISHA, Aichi (JP)

(72) Inventors: Kazuhiko Kusunoki, Nishinomiya-shi (JP); Kazuhito Kamei, Kitakyushu-shi (JP); Nobuyoshi Yashiro, Itami-shi (JP); Nobuhiro Okada, Kisarazu-shi (JP); Koji Moriguchi, Nishinomiya-shi (JP); Motohisa Kado, Gotemba-shi (JP); Hironori Daikoku, Susono-shi (JP); Hidemitsu Sakamoto, Susono-shi (JP)

(73) Assignee: TOYOTA JIDOSHA KABUSHIKI KAISHA, Aichi (JP)

(21) Appl. No.: 14/424,538

(22) PCT Filed: Sep. 2, 2013
(86) PCT No.: PCT/JP2013/005168

§ 371 Date: Feb. 27, 2015

(30) Foreign Application Priority Data
Sep. 4, 2012 (JP) 2012-193725

(51) Int. Cl. C30B 19/04; C30B 29/36

(52) U.S. Cl. CPC C30B 19/04; C30B 29/36

(57) ABSTRACT

A SiC single crystal production apparatus is used in production of SiC single crystals by solution growth techniques. The apparatus includes: a seed shaft having a lower end surface to which a SiC seed crystal is to be attached; a crucible that contains a Si—C solution; a stirring member that is immersed in the Si—C solution; and drive sources that cause relative rotation between the crucible and the stirring member. The lower end of the stirring member is located lower than the lower end of the SiC seed crystal attached to the lower end surface of the seed shaft.

### TECHNICAL FIELD

The present invention relates to a SiC single crystal production apparatus and a method of producing SiC single crystals, and in particular relates to a production apparatus for use in producing SiC single crystals by solution growth techniques and a method of producing SiC single crystals by solution growth techniques.

### BACKGROUND ART

As a method of producing SiC single crystals, solution growth techniques are known. In solution growth techniques, a SiC seed crystal made from a SiC single crystal is brought into contact with a Si—C solution. A Si—C solution herein means a solution of a Si or Si alloy melt in which carbon (C) is dissolved. In the Si—C solution, a region near the SiC seed crystal is supercooled, whereby a SiC single crystal is grown on the surface of the SiC seed crystal.

In solution growth techniques, if variations in the growth rate occur at the growth interface, minute irregularities (having a smaller spacing than the width of the SiC seed crystal) are formed in the surface of the SiC single crystal that is being produced. If the irregularities become larger, the solvent is trapped in the recesses. As a result, the solvent is entrapped within the SiC single crystal that is being produced, so that inclusions occur. If inclusions occur, it is impossible to produce a SiC single crystal of good quality. Therefore, it is important to inhibit the variations in the growth rate at the growth interface in order to produce a SiC single crystal of good quality and of large thickness (i.e., a growth thickness of several millimeters or more).

It is believed that the variations in the growth rate at the growth interface are attributable to variations in the concentration of the solute (SiC) in the Si—C solution and variations in the temperature at the growth interface. Thus, it is important to inhibit the variations in the concentration of the solute and variations in the temperature at the growth interface.

Japanese Patent Application Publication No. 2006-117441 discloses a method of producing SiC single crystals in which the rotational speed of a crucible, or the rotational speed and the rotational direction of the crucible are periodically varied to cause the melt to flow in the crucible. Varying the rotational speed of the crucible causes a forced flow in the melt in the crucible. Because of this, a non-uniform supply of solute at the growth interface is remedied, and therefore step bunching is inhibited. As a result, entrapment of solvent between steps is inhibited and the occurrence of inclusions is inhibited.

### CITATION LIST

### Patent Literature

Patent Literature 1: Japanese Patent Application Publication No. 2006-117441

### SUMMARY OF INVENTION

### Technical Problem

However, with the above-described production method, minute irregularities are still formed when the growth thickness is several millimeters or more, and therefore the production of SiC single crystals of good quality is difficult. This is due to the fact that, when growing a SiC single crystal of large thickness, the central region thereof and the peripheral region thereof tend to have different thicknesses because of the difference in the growth rate between the central region and the peripheral region. In such a case, the growth interface of the SiC single crystal becomes a convex surface or a concave surface in which steps are present when observed microscopically. If step bunching occurs at this growth interface, steps as minute irregularities are formed, and thus there is the possibility that the solvent is entrapped therein and inclusions occur. Hence, with the above-described production method, when a SiC single crystal having a large thickness is to be produced, the influence of the difference in the growth rate between the central region and the peripheral region at the growth interface becomes non-negligible.

An object of the present invention is to provide a SiC single crystal production apparatus and a method of producing SiC single crystals which are capable of inhibiting variations in the growth rate at the growth interface.

### Solution to Problem

SiC single crystal production apparatus according to embodiments of the present invention is used in production of SiC single crystals by solution growth techniques. The SiC single crystal production apparatus includes a seed shaft, a crucible, a stirring member, and a drive source. The seed shaft has a lower end surface to which a SiC seed crystal is to be attached. The crucible contains a Si—C solution. The stirring member is immersed in the Si—C solution and is arranged so that the lower end of the stirring member is located lower than the lower end of the SiC seed crystal attached to the lower end surface of the seed shaft. The drive source causes relative rotation between the crucible and the stirring member.

Methods of producing SiC single crystals according to embodiments of the present invention uses the SiC single crystal production apparatus as described above. The production method includes the steps of: forming a Si—C solution; immersing a stirring member in the Si—C solution; and bringing a SiC seed crystal into contact with the Si—C solution and growing a SiC single crystal, wherein the step of growing a SiC single crystal includes causing relative rotation between the crucible and the stirring member, with the lower end of the stirring member being located lower than the lower end of the SiC seed crystal attached to the lower end surface of the seed shaft.

### Advantageous Effects of Invention

SiC single crystal production apparatus and methods of producing SiC single crystals according to embodiments of the present invention are capable of inhibiting variations in the growth rate at the growth interface.

### BRIEF DESCRIPTION OF DRAWINGS

FIG. 1 is a schematic diagram of a single crystal production apparatus according to an embodiment of the present invention.

FIG. 2 is a plan view of an impeller which is a stirring member included in the production apparatus shown in FIG. 1.

FIG. 3 is a schematic diagram showing Variation 1 of the stirring member.

FIG. 4A is a schematic diagram showing Variation 2 of the stirring member.

FIG. 4B is a schematic diagram showing Variation 3 of the stirring member.

FIG. 4C is a schematic diagram showing Variation 4 of the stirring member.

FIG. 4D is a schematic diagram showing Variation 5 of the stirring member.

FIG. 4E is a schematic diagram showing Variation 6 of the stirring member.

FIG. 4F is a schematic diagram showing Variation 7 of the stirring member.

FIG. 4G is a schematic diagram showing Variation 8 of the stirring member.

FIG. 5 is a graph showing the ratio of the thickness of the central region of a grown SiC single crystal to the thickness of the peripheral region thereof.

### DESCRIPTION OF EMBODIMENTS

SiC single crystal production apparatus according to embodiments of the present invention is used in production of SiC single crystals by solution growth techniques. The SiC single crystal production apparatus includes a seed shaft, a crucible, a stirring member, and a drive source. The seed shaft has a lower end surface to which a SiC seed crystal is to be attached. The crucible contains a Si—C solution. The stirring member is immersed in the Si—C solution and is arranged so that the lower end of the stirring member is located lower than the lower end of the SiC seed crystal attached to the lower end surface of the seed shaft. The drive source causes relative rotation between the crucible and the stirring member.

Thus, relative rotation takes place between the crucible and the stirring member. Consequently, the Si—C solution is stirred by the stirring member. Since the lower end of the stirring member is located lower than the lower end of the SiC seed crystal attached to the lower end surface of the seed shaft, the Si—C solution in a region lower than the lower end of the SiC seed crystal is stirred. Stirring the Si—C solution using the stirring member in this manner facilitates the flow of the Si—C solution in the vicinity of the growth interface of the SiC single crystal. Because of this, the temperature distribution of the Si—C solution and the distribution of the concentration of the solute included in the Si—C solution become uniform more easily in the vicinity of the growth interface of the SiC single crystal. As a result, it is possible to inhibit variations in the growth rate at the growth interface.

Preferably, the drive source includes a first drive source that causes the crucible to rotate. In this case, the relative rotation between the crucible and the stirring member can be effected by rotating the crucible.

The drive source preferably includes a second drive source in addition to the first drive source. The second drive source causes the stirring member to rotate about the central axis of the seed shaft.

The relative rotation between the crucible and the stirring member may be accomplished by rotating both the crucible and the stirring member or by rotating either the crucible or the stirring member.

Preferably, the stirring member is rotated by the second drive source in a direction opposite to the rotational direction of the crucible. In such a case, the relative rotational speed of the stirring member to the rotational speed of the crucible is increased. As a result, the stirring of the Si—C solution in the crucible becomes even easier.

Preferably, the stirring member is placed below the SiC seed crystal. In this case, the stirring member is arranged to oppose the SiC seed crystal on the central axis of the seed shaft, and thus the Si—C solution in the vicinity of the crystal growth interface of the SiC seed crystal can be stirred easily.

Preferably, the stirring member is an impeller that is rotatable about the central axis of the seed shaft. “Impeller” as used herein refers to a component including plate-shaped members rotatable about a rotatable shaft. With this, it is possible to efficiently stir the Si—C solution. The impeller may be of a type having blades that are oriented obliquely with respect to the central axis of the seed shaft (e.g., propeller), and in this case, the blades may be rotatable about the central axis of the seed shaft. In this case, by causing relative rotation between the crucible and the stirring member, it is possible to generate an upward flow or a downward flow in the Si—C solution by the impeller.

The stirring member may be attached to the seed shaft. In this case, the seed shaft may be rotated by a drive source. Alternatively, the stirring member may not be attached to the seed shaft. In such a case, for example, the seed shaft and the stirring member may each be rotated independently by different drive sources.

In either case, when the seed shaft is rotated, the relative rotation between the crucible and the stirring member can be effected.

Methods of producing SiC single crystals according to embodiments of the present invention use the production apparatus as described above.

Hereinafter, embodiments of the present invention will be described with reference to the drawings. The same reference symbols will be used throughout the drawings to refer to the same or like parts, and a description thereof will not be repeated.

### [Production Apparatus]

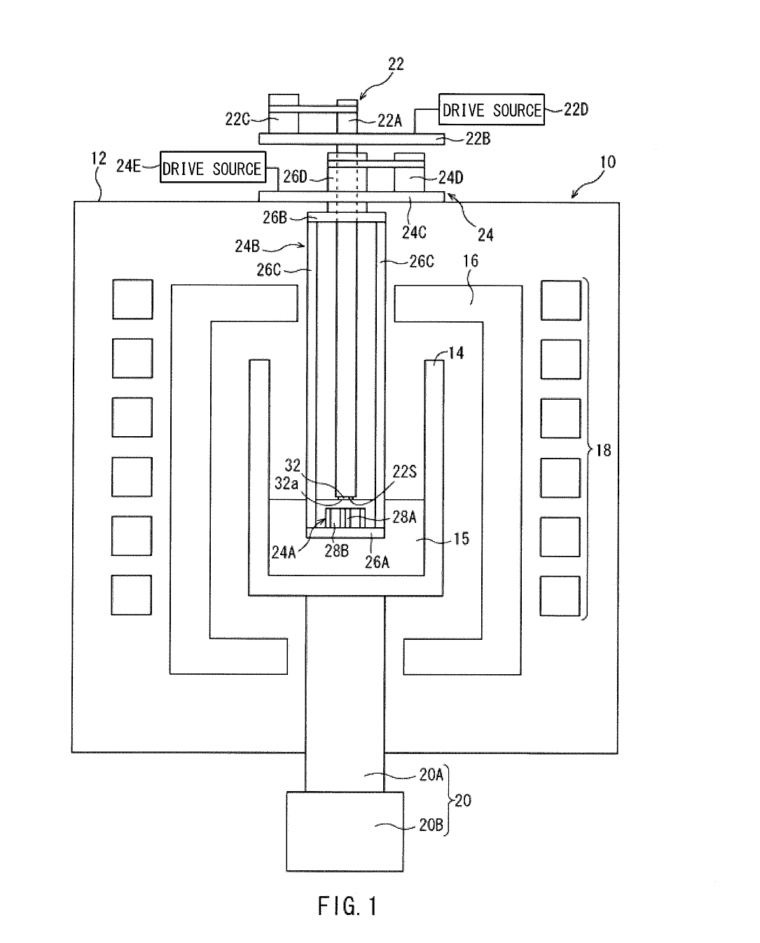

FIG. 1 is a schematic diagram showing a configuration of a SiC single crystal production apparatus 10 according to an embodiment of the present invention. The production apparatus 10 includes a chamber 12, a crucible 14, an insulating member 16, a heating device 18, a first driving device 20, and a second driving device 22, and a third driving device 24.

The chamber 12 accommodates the crucible 14. During the production of a SiC single crystal, the chamber 12 is cooled.

The crucible 14 contains a Si—C solution 15. The Si—C solution 15 is a material from which a SiC single crystal is made. The Si—C solution 15 includes silicon (Si) and carbon (C).

The raw material for the Si—C solution 15 is, for example, Si alone or a mixture of Si and another metal element. The raw material is heated to form a melt, and carbon (C) is dissolved in the melt, whereby the Si—C solution 15 is formed. Examples of another metal element include titanium (Ti), manganese (Mn), chromium (Cr), cobalt (Co), vanadium (V) and iron (Fe). Of these metal elements, preferred metal elements are Ti, Cr, and Fe. More preferred metal elements are Ti and Cr.

Preferably, the crucible 14 includes carbon. When this is the case, the crucible 14 serves as a source of carbon that is supplied to the Si—C solution 15. The crucible 14 may be a crucible made of graphite or a crucible made of SiC, for example. The crucible 14 may have a SiC coating on its internal surface.

The insulating member 16 is made of insulating material and surrounds the crucible 14.

The heating device 18 may be, for example, a high frequency coil, and surrounds side walls of the insulating member 16. The heating device 18 heats the crucible 14 that contains the raw material for the Si—C solution 15 by induction heating, so that the Si—C solution 15 is formed. Further, the heating device 18 maintains the Si—C solution 15 at the crystal growth temperature. The crystal growth temperature depends on the composition of the Si—C solution 15. The crystal growth temperature is, for example, 1600 to 2000° C.

The first driving device 20 includes a rotatable shaft 20A and a drive source 20B.

The rotatable shaft 20A extends in the height direction of the chamber 12 (the vertical direction in FIG. 1). The upper end of the rotatable shaft 20A is located inside the insulating member 16. The crucible 14 is placed at the upper end of the rotatable shaft 20A. The lower end of the rotatable shaft 20A is located outside the chamber 12.

The drive source 20B is placed below the chamber 12. The drive source 20B is connected to the rotatable shaft 20A. The drive source 20B causes the rotatable shaft 20A to rotate about the central axis of the rotatable shaft 20A. With this, the crucible 14 (Si—C solution 15) rotates about the central axis.

The second driving device 22 includes a seed shaft 22A, a support holder 22B, a drive source 22C, and a drive source 22D.

The seed shaft 22A extends in the height direction of the chamber 12. The seed shaft 22A is made of graphite, for example. The upper end of the seed shaft 22A is located outside the chamber 12. A SiC seed crystal 32 is to be attached to the lower end surface 22S of the seed shaft 22A.

The SiC seed crystal 32 is in the shape of a plate, and the top surface thereof is to be attached to the lower end surface 22S. In the present embodiment, the entire top surface of the SiC seed crystal 32 is in contact with the lower end surface 22S. The lower surface of the SiC seed crystal 32 serves as the crystal growth surface.

The SiC seed crystal 32 is made of a SiC single crystal. Preferably, the SiC seed crystal 32 has the same crystal structure as that of the SiC single crystal that is to be produced. For example, when a SiC single crystal of a 4H polytype is to be produced, a SiC seed crystal 32 of a 4H polytype is used. When a SiC seed crystal 32 of a 4H polytype is used, it is preferred that the crystal growth surface be the (0001) plane or a plane that is 8° or less off-axis from the (0001) plane. In such a case, SiC single crystals are grown stably.

The support holder 22B is placed above the chamber 12. The support holder 22B has an opening through which the seed shaft 22A is inserted. The support holder 22B supports the seed shaft 22A and the drive source 22C. The seed shaft 22A is relatively rotatable with respect to the support holder 22B about the central axis of the seed shaft 22A. Also, the seed shaft 22A is movable in the vertical direction together with the support holder 22B.

The drive source 22C causes the seed shaft 22A to rotate about the central axis of the seed shaft 22A. With this, the SiC seed crystal 32 attached to the lower end surface 22S of the seed shaft 22A rotates.

The drive source 22D is placed outside the chamber 12. The drive source 22D lifts and lowers the support holder 22B. With this, the seed shaft 22A moves up and down. As a result, the crystal growth surface of the SiC seed crystal 32 attached to the lower end surface 22S of the seed shaft 22A can be brought into contact with the surface of the Si—C solution 15 contained in the crucible 14.

The third driving device 24 includes a stirring member 24A, a support member 24B, a support holder 24C, a drive source 24D, and a drive source 24E.

The stirring member 24A is immersed in the Si—C solution 15. The stirring member 24A is an impeller that is rotatable about the central axis of the seed shaft 22A. In the present embodiment, the stirring member 24A is a so-called paddle impeller. The stirring member 24A is placed below the SiC seed crystal 32 on the central axis of the seed shaft 22A, and opposes the SiC seed crystal 32. In this embodiment, the stirring member 24A as a whole is located lower than the lower end 32a of the SiC seed crystal 32.

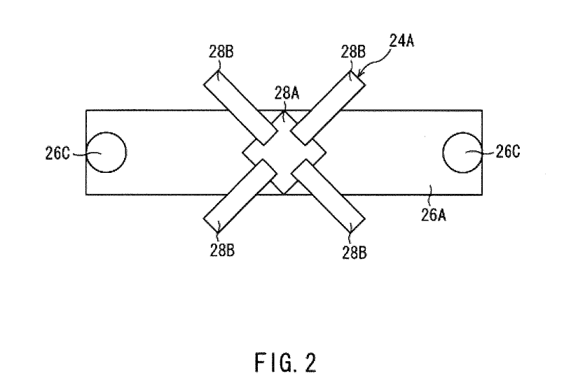

As shown in FIG. 2, the stirring member 24A includes a shaft 28A and a plurality of (in the present embodiment, four) blades 28B (plate-shaped members). The shaft 28A is arranged coaxially with the seed shaft 22A and supports the plurality of blades 28B in such a manner that they are parallel to the central axis and extend radially from the central axis. The plurality of blades 28B are circumferentially equiangularly spaced about the central axis of the shaft 28A.

Referring back to FIG. 1, the following description is given. The support member 24B includes a first support portion 26A, a second support portion 26B, and a pair of connecting portions 26C, 26C.

The first support portion 26A is placed below the SiC seed crystal 32 and supports the stirring member 24A. The stirring member 24A is placed between the first support portion 26A and the seed crystal 32.

The second support portion 26B is placed above the crucible 14. The second support portion 26B has an opening through which the seed shaft 22A is inserted. The second support portion 26B includes a drive shaft 26D arranged coaxially with the seed shaft 22A. At least the upper end of the drive shaft 26D is located above the chamber 12. Driving force of the drive source 24D is transmitted to the drive shaft 26D.

The pair of connecting portions 26C, 26C extends in the vertical direction and connects the first support portion 26A with the second support portion 26B.

The support holder 24C is placed above the chamber 12. The support holder 24C has an opening through which the seed shaft 22A and the support member 24B (drive shaft 26D) are inserted. The support holder 24C supports the support member 24B and the drive source 24D. The support member 24B is relatively rotatable with respect to the support holder 24C about the central axis of the seed shaft 22A. Also, the support member 24B is movable in the vertical direction together with the support holder 24C.

The drive source 24D causes the support member 24B to rotate (e.g., rotate in a steady state) about the central axis of the seed shaft 22A. With this, the stirring member 24A rotates about the central axis of the seed shaft 22A.

The drive source 24E is placed outside the chamber 12. The drive source 24E lifts and lowers the support holder 24C. With this, the stirring member 24A moves up and down. As a result, the stirring member 24A can be immersed in the Si—C solution 15 contained in the crucible 14.

### [Method of Producing a SiC Single Crystal]

Methods of producing SiC single crystals using the production apparatus 10 are described. Firstly, the production apparatus 10 is prepared (preparation step). Next, the SiC seed crystal 32 is attached to the seed shaft 22A (attaching step). Next, the crucible 14 is placed within the chamber 12 and the Si—C solution 15 is formed (forming step). Next, the stirring member 24A is immersed in the Si—C solution 15 (immersing step). Next, the SiC seed crystal 32 is brought into contact with the Si—C solution 15 in the crucible 14 (contacting step). Next, a SiC single crystal is grown (growing step). Details of each step are described below.

### [Preparation Step]

Firstly, the production apparatus 10 is prepared.

### [Attaching Step]

Then, the SiC seed crystal 32 is attached to the lower end surface 22S of the seed shaft 22A. In the present embodiment, the entire top surface of the SiC seed crystal 32 is in contact with the lower end surface 22S of the seed shaft 22A.

### [Forming Step]

Next, the crucible 14 is placed on the rotatable shaft 20A within the chamber 12. The crucible 14 contains raw materials for the Si—C solution 15.

Next, the Si—C solution 15 is formed. Firstly, the chamber 12 is filled with an inert gas. Then, the raw material for the Si—C solution 15 in the crucible 14 is heated to its melting point (liquidus temperature) or higher using the heating device 18. When the crucible 14 is one made of graphite, carbon from the crucible 14 is dissolved into the melt by heating the crucible 14, so that the Si—C solution 15 is formed. As the carbon in the crucible 14 is dissolved in the Si—C solution 15, the carbon concentration in the Si—C solution 15 approaches a saturation concentration.

### [Immersing Step]

Next, the support holder 24C is lowered by the drive source 24E to immerse the stirring member 24A in the Si—C solution 15.

### [Contacting Step]

Next, the support holder 22B is lowered by the drive source 22D to bring the crystal growth surface of the SiC seed crystal 32 into contact with the Si—C solution 15.

### [Growing Step]

After the crystal growth surface of the SiC seed crystal 32 is brought into contact with the Si—C solution 15, the Si—C solution 15 is held at the crystal growth temperature by the heating device 18. Further, in the Si—C solution 15, a region near the SiC seed crystal 32 is supercooled so that it is supersaturated with SiC.

The method of supercooling the region near the SiC seed crystal 32 in the Si—C solution 15 is not particularly limited. For example, one possible method is to control the heating device 18 so that the temperature of the region near the SiC seed crystal 32 in the Si—C solution 15 can be reduced to a level lower than the temperatures of the other regions. Alternatively, a coolant may be used to cool the vicinity of the SiC seed crystal 32 in the Si—C solution 15. Specifically, a coolant is circulated within the seed shaft 22A. The coolant may be, for example, an inert gas such as helium (He) or argon (Ar). When a coolant is circulated within the seed shaft 22A, the SiC seed crystal 32 is cooled. When the SiC seed crystal 32 is cooled, the region near the SiC seed crystal 32 in the Si—C solution 15 is also cooled.

While the region near the SiC seed crystal 32 in the Si—C solution 15 is held in the SiC supersaturated condition, relative rotation between the stirring member 24A and the crucible 14 is caused, with the lower end of the stirring member 24A being located lower than the lower end of the SiC seed crystal 32 attached to the lower end surface of the seed shaft 22A. In this embodiment, the stirring member 24A as a whole is located lower than the lower end of the SiC seed crystal 32. The rotation here may be a steady-state rotation or may not be a steady-state rotation.

Methods for causing relative rotation between the stirring member 24A and the crucible 14 include: for example, (1) rotating the crucible 14 while the stirring member 24A is held stationary; (2) while the crucible 14 is rotated, rotating the stirring member 24A in a direction opposite to the rotational direction of the crucible 14; (3) rotating the stirring member 24A while the crucible 14 is held stationary; and (4) rotating the crucible 14 and the stirring member 24A in the same direction but at different rotational speeds.

When rotating the stirring member 24A in a direction opposite to the rotational direction of the crucible 14 while the crucible 14 is rotated, the rotational speed of the crucible 14 and the rotational speed of the stirring member 24A may be the same or may be different from each other.

The seed shaft 22A may be rotated or may not be rotated. When the seed shaft 22A is rotated, the seed shaft 22A may be rotated in the same direction as the rotational direction of the crucible 14 or may be rotated in a direction opposite thereto. The seed shaft 22A may be lifted or may not be lifted.

According to the production method described above, relative rotation takes place between the crucible 14 and the stirring member 24A. Consequently, the Si—C solution 15 is stirred by the stirring member 24A. As a result, the Si—C solution 15 in the vicinity of the growth interface of the SiC single crystal can flow more easily than the case where no stirring member 24A is provided and merely the crucible 14 is rotated. Since the lower end of the stirring member 24A is located lower than the lower end of the SiC seed crystal 32 attached to the lower end surface of the seed shaft 22A, the Si—C solution in a region lower than the lower end of the SiC seed crystal 32 is stirred efficiently. Because of this, the temperature distribution of the Si—C solution 15 and the distribution of the concentration of the solute included in the Si—C solution 15 become uniform more easily in the vicinity of the growth interface of the SiC single crystal. As a result, it is possible to inhibit variations in the growth rate at the growth interface. In this embodiment, regions of the connecting portions 26C that are immersed in the Si—C solution 15 and located lower than the lower end of the SiC seed crystal 32 as well as the first support portion 26A as a whole also serve as stirring members in the present invention.

Preferably, the stirring member 24A is rotated in a direction opposite to the rotational direction of the crucible 14. With this, the relative rotational speed of the stirring member 24A to the rotational speed of the crucible 14 is increased. As a result, the Si—C solution 15 in the crucible 14 can be stirred more easily.

In the above embodiment, the stirring member 24A is arranged below the SiC seed crystal 32 in such a manner as to oppose the crystal growth surface that constitutes the lower end of the SiC seed crystal 32. Because of this, the Si—C solution 15 in the vicinity of the growth interface of the SiC single crystal can be stirred more easily.

In the above embodiment, the stirring member 24A is an impeller (paddle impeller). Thus, it is possible to efficiently stir the Si—C solution 15.

### [Variation 1 of Stirring Member]

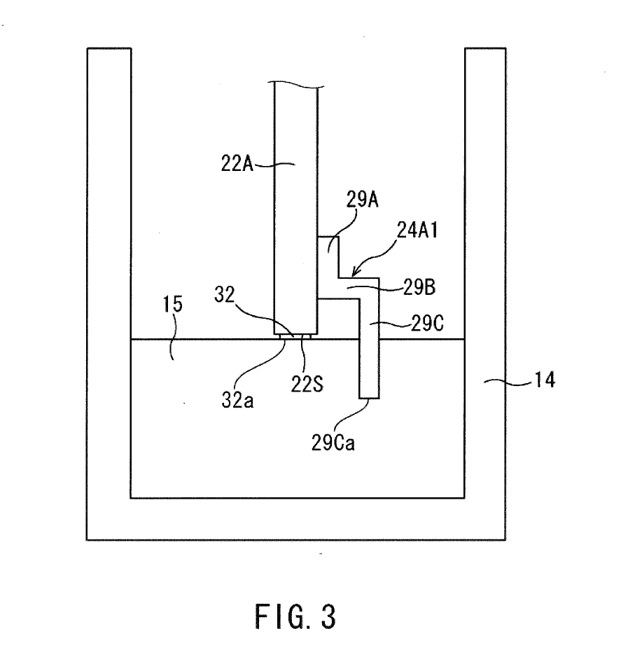

As shown in FIG. 3, for example, a stirring member 24A1 may be attached to the seed shaft 22A. The stirring member 24A1 includes an attachment portion 29A, an extending portion 29B, and a stirring portion 29C.

The attachment portion 29A is attached to the seed shaft 22A. The extending portion 29B extends in the horizontal direction from the lower end of the attachment portion 29A. The stirring portion 29C extends downwardly from one end (extended end) of the extending portion 29B. The stirring portion 29C is immersed in the Si—C solution 15. The lower end 29Ca of the stirring portion 29C constitutes the lower end of the stirring member 24A1 and is located lower than the lower end 32a of the SiC seed crystal 32. Because of such a configuration that at least a portion of the stirring member 24A1 is located lower than the lower end 32a of the SiC seed crystal 32, it is possible to efficiently stir the Si—C solution in a region lower than the lower end 32a of the SiC seed crystal 32. As in this variation, it is not required in the present invention that the entire body of the stirring member is located lower than the lower end 32a of the SiC seed crystal 32 like the stirring member 24A shown in FIG. 1.

In such a configuration of the stirring member 24A1, the stirring member 24A1 is rotated about the central axis of the seed shaft 22A by rotating the seed shaft 22A. Thus, there is no need to provide a drive source exclusively for rotating the stirring member 24A1. As a result, the configuration of the production apparatus is simplified.

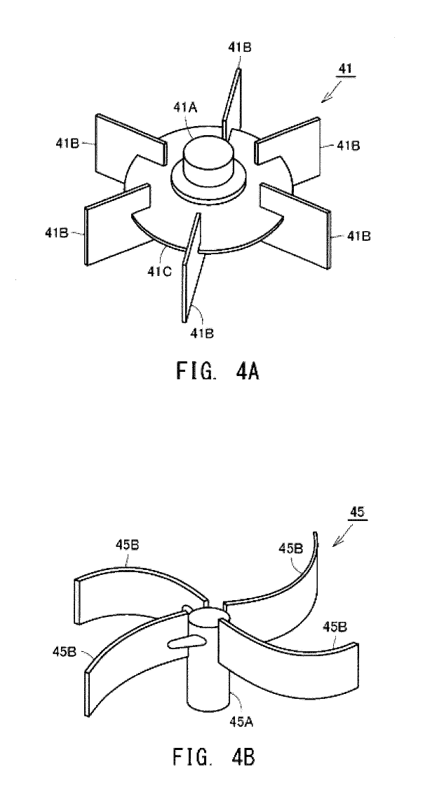

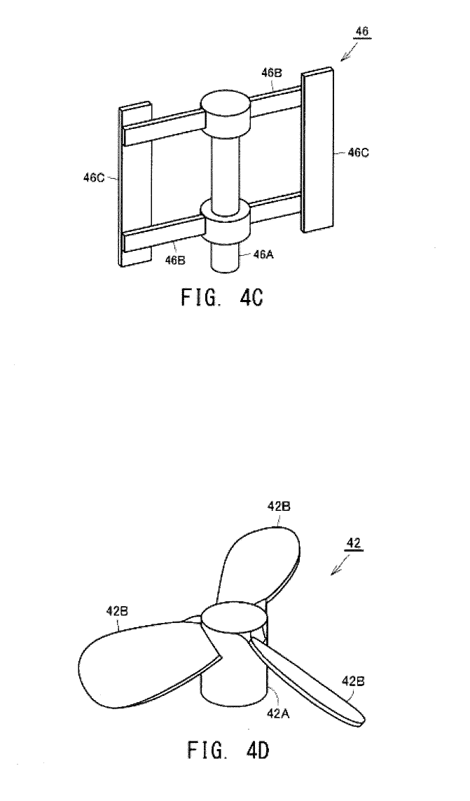

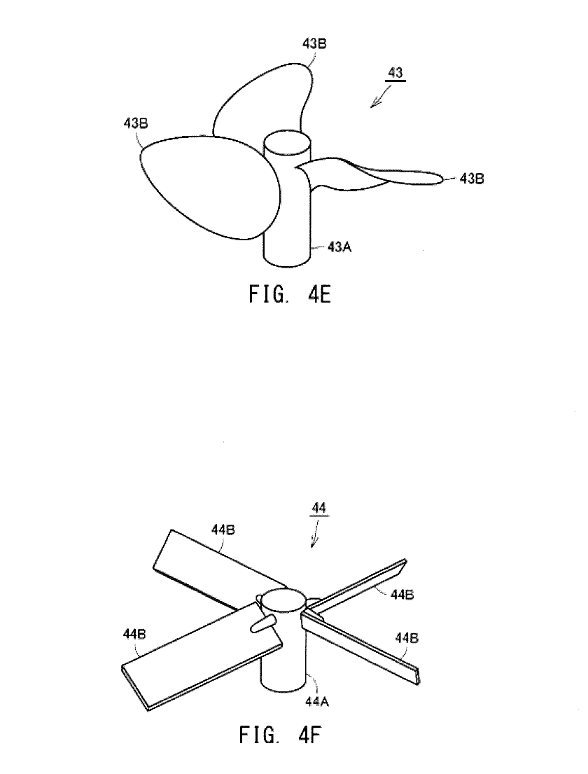

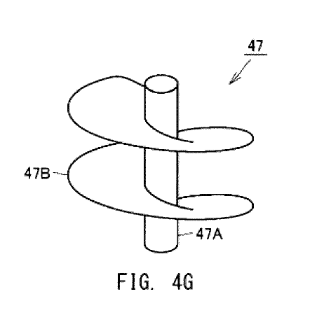

Hereinafter, as variations of the stirring member (impeller), those that can be used in the production apparatus 10 shown in FIG. 1 in place of the stirring member 24A by being attached on the first support portion 26A are described with reference to FIGS. 4A to 4G. The stirring members of Variations below, when used in place of the stirring member 24A in this manner, rotates about the central axis of the seed shaft 22A.

### [Variation 2 of Stirring Member]

The stirring member 41 shown in FIG. 4A is a so-called turbine. It includes a shaft 41A, a disc 41C that is coaxially attached to the shaft 41A, and a plurality of (in the present embodiment, six) blades 41B (plate-shaped members) that are attached to the disc 41C. The plurality of blades 41B are circumferentially equiangularly spaced with respect to the central axis of the shaft 41A, and are attached to the disc 41C in such a manner that they are parallel to the shaft 41A and extend radially with respect to the shaft 41A. The blades 41B are substantially parallel to the shaft 41A and also are substantially orthogonal to the disc 41C.

With the stirring member 41 of this Variation, it is easier to position the blades 41B (28B) farther away from the shaft 41A (28A) than with the stirring member 24A shown in FIGS. 1 and 2. Thus, the stirring member 41 of this Variation is suitable for stirring the Si—C solution 15 in a region far from the shaft 41A (28A).

### [Variation 3 of Stirring Member]

The stirring member 45 shown in FIG. 4B includes a shaft 45A and a plurality of (in the present embodiment, four) blades 45B. The blades 45B each have a curved shape such that their radially intermediate portions project in one rotational direction about the shaft 45A. The principal plane of each blade 45B has a generatrix that is substantially parallel to the shaft 45A. Because of the curved shape of the blades 45B, it is possible to impart different stirring forces to the Si—C solution 15 depending on the rotational direction of the crucible 14 and/or the stirring member 45 about the axis even if the rotation speed is unchanged. Specifically, when the Si—C solution 15 is received on the concave surface of the blade 45B rather than the convex surface thereof, a stronger stirring force is imparted to the Si—C solution 15. For example, in FIG. 4B, the stirring member 45 imparts a stronger stirring force to the Si—C solution when it rotates counterclockwise than when it rotates clockwise.

### [Variation 4 of Stirring Member]

The stirring member 46 shown in FIG. 4C includes a shaft 46A, a plurality of (in the present embodiment, two) support bars 46B that extend from the shaft 46A in radially opposite directions of the shaft 46A, and blades 46C that are attached to one ends and the opposite ends of the plurality of support bars 46B. The plurality of support bars 46B extend substantially parallel to each other, in a direction substantially orthogonal to the shaft 46A. The blades 46C are in the shape of an elongated plate and extend substantially parallel to the shaft 46A.

When this stirring member 46 is used, the Si—C solution 15 is stirred by the blades 46C and the support bars 46B, whereas the Si—C solution 15 present in a space surrounded by the shaft 46A, the support bars 46B, and the blades 46C is not directly stirred. This makes it possible to form a complex flow in the Si—C solution 15.

### [Variation 5 of Stirring Member]

The stirring member 42 shown in FIG. 4D is a so-called propeller and includes a shaft 42A and a plurality of (in the present embodiment, three) blades 42B. The blades 42B have a rounded contour. The blades 42B are disposed obliquely with respect to the shaft 42A. When the stirring member 42 is used in place of the stirring member 24A in the production apparatus 10 of FIG. 1, the blades 42B are oriented obliquely with respect to the central axis of the seed shaft 22A and are rotatable about the central axis of the seed shaft 22A.

With this, by causing relative rotation between the crucible 14 and the stirring member 42, it is possible to generate an upward flow or a downward flow in the Si—C solution 15 in the vicinity of the stirring member 42 depending on the rotational direction of the crucible 14 and/or the stirring member 42 about the axis.

If there is a tendency for the SiC crystal that grows on the SiC seed crystal 32 to grow into a convex shape (thicker in the central region than in the peripheral region) when the stirring member 42 is not provided, it is preferred that the crucible 14 and/or the stirring member 42 be rotated in such a manner that a downward flow of the Si—C solution 15 is generated on the vertical axis passing through the central region of the SiC crystal. On the other hand, if there is a tendency for the SiC crystal that grows on the SiC seed crystal 32 to grow into a concave shape (thinner in the central region than in the peripheral region) when the stirring member 42 is not provided, it is preferred that the crucible 14 and/or the stirring member 42 be rotated in such a manner that an upward flow of the Si—C solution 15 is generated on the vertical axis passing through the central region of the SiC crystal. In these cases, it is possible to reduce the difference in thickness between the central region and the peripheral region, in the SiC crystal, compared to the case where the stirring member 42 is not provided.

### [Variation 6 of Stirring Member]

The stirring member 43 shown in FIG. 4E is a so-called propeller like the stirring member 42 shown in FIG. 4D and includes a shaft 43A and a plurality of (in the present embodiment, three) blades 43B having a principal plane with a rounded contour. With the use of this stirring member 43, it is possible to produce a similar effect as in the case of using the stirring member 42. In the stirring member 43 of this Variation, the blades 43B have a width greater than the width of the blades 42B of the stirring member 42. This makes it possible to increase the efficiency of stirring.

### [Variation 7 of Stirring Member]

The stirring member 44 shown in FIG. 4F is a so-called propeller like the stirring members 42, 43 shown in FIGS. 4D and 4E and includes a shaft 44A and a plurality of (in the present embodiment, four) blades 44B. The blades 44B have a substantially rectangular principal plane unlike the blades 42B, 43B. As in this case, the blades 44B may not necessarily be round-shaped.

### [Variation 8 of Stirring Member]

The stirring member 47 shown in FIG. 4G includes a shaft 47A and a helical blade 47B helically attached about the shaft 47A. When the stirring member 47 is used in the production apparatus 10 of FIG. 1 in place of the stirring member 24A, the stirring member 47 is rotatable about the central axis of the seed shaft 22A and the helical blade 47B is oriented obliquely with respect to the central axis of the seed shaft 22A.

Because of such a helical blade 47B that is included in the stirring member 47, it is possible to generate an upward flow or a downward flow in the Si—C solution 15, in the vicinity of the stirring member 47, depending on the rotational direction of the crucible 14 and/or the stirring member 47 about the axis. Thus, with the stirring member 47, it is possible to produce a similar effect as with the stirring members 42 to 44.

### EXAMPLES

SiC single crystals were produced using a production apparatus shown in FIG. 1, and the thickness ratio of the thickness of the peripheral region to that of the central region, of the produced SiC single crystals, (the thickness of the peripheral region/the thickness of the central region) was investigated (Examples 1 and 2).

### Production Conditions for Examples 1 and 2

In Example 1, during the crystal growth process, the seed shaft and the crucible were rotated in a steady state while the stirring member was held stationary. The rotational speed of the seed shaft was 20 rpm. The rotational speed of the crucible was 20 rpm. The seed shaft was rotated in a direction opposite to the rotational direction of the crucible. The growth temperature was about 1950° C. The period of time for crystal growth was 45 hours.

In Example 2, during the crystal growth process, the seed shaft and the crucible were rotated in a steady state while the stirring member was rotated in a steady state. The rotational speed of the seed shaft was 20 rpm. The rotational speed of the crucible was 20 rpm. The rotational speed of the stirring member was 20 rpm. The seed shaft was rotated in a direction opposite to the rotational direction of the crucible. The stirring member was rotated in a direction opposite to the rotational direction of the crucible. The growth temperature was about 1950° C. The period of time for crystal growth was 52 hours.

In addition, for comparison, a SiC single crystal was produced using a production apparatus similar to the one shown in FIG. 1 but not having a stirring member, and the thickness ratio of the thickness of the peripheral region to that of the central region, of the produced SiC single crystal, was investigated (Comparative Example).

### Production Conditions for Comparative Example

In Comparative Example, during the crystal growth process, the rotational speed of the crucible was periodically varied while the seed shaft was held stationary. The preset rotational speed was 20 rpm. The length of time from the start of rotation to the time the preset rotational speed was reached was 5 seconds. The length of time in which the preset rotational speed was maintained was 30 seconds. The length of time from the rotation at the preset rotational speed to the time the rotation was stopped was 5 seconds. Such a rotation process was designated as one cycle, and this cycle was repeated. The crystal growth temperature was about 1950° C. The period of time for crystal growth was 12 hours.

### [Investigation Procedure]

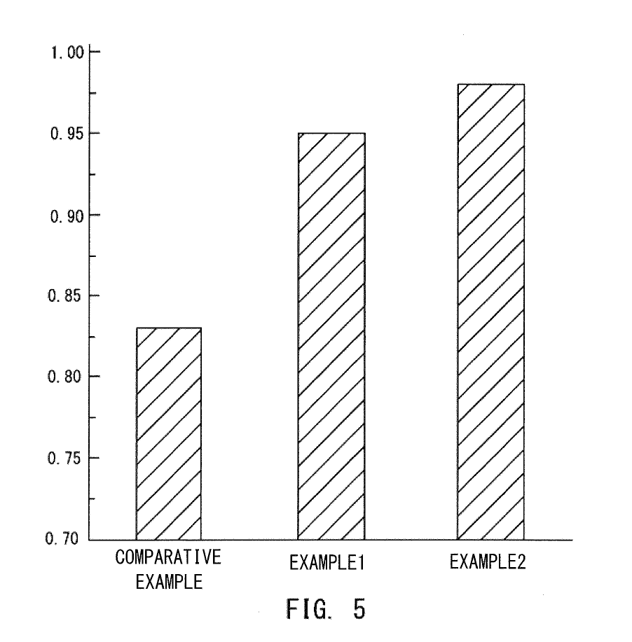

For each of the SiC single crystals of Examples 1 and 2 and Comparative Example, photographs of the cross section of the SiC single crystal were taken, and the thickness of the central region and the thickness of the peripheral region were measured. In Example 1, the thickness of the central region was 1.27 mm and the thickness of the peripheral region was 1.21 mm. In Example 2, the thickness of the central region was 2.26 mm and the thickness of the peripheral region was 2.22 mm. In Comparative Example, the thickness of the central region was 1.19 mm and the thickness of the peripheral region was 0.99 mm. The thickness ratio was determined by dividing the thickness of the peripheral region by the thickness of the central region, both obtained by the measurement. The thickness ratio of each of the SiC single crystals is shown in FIG. 5.

### [Investigation Result]

It was observed that, when a production apparatus including a stirring member was used, variations in the growth rate at the growth interface can be inhibited compared to the case where a production apparatus having no stirring member was used. Thus, the SiC single crystals of Examples 1 and 2 each had a thickness ratio closer to 1 than the SiC single crystal of Comparative Example. That is, the flatness of the produced SiC single crystals was improved. The reason for this is believed to be that, when a production apparatus including a stirring member was used, the temperature distribution of the Si—C solution and the distribution of the concentration of the solute included in the Si—C solution became uniform in the vicinity of the growth interface of the SiC single crystal compared to the case where a production apparatus having no stirring member was used.

It was observed that variations in the growth rate at the growth interface can be inhibited to a greater extent when the stirring member was rotated in a steady state and concurrently the crucible was rotated in a steady state in a direction opposite to the rotational direction of the stirring member, than the case where the crucible was rotated in a steady state while the stirring member was held stationary. Thus, the SiC single crystal of Example 2 had a thickness ratio closer to 1 than the SiC single crystal of Example 1. That is, the flatness of the produced SiC single crystal was improved. The reason for this is believed to be that the temperature distribution of the Si—C solution and the distribution of the concentration of the solute included in the Si—C solution, in the vicinity of the growth interface of the SiC single crystal, became uniform to a greater extent.

Although specific embodiments of the present invention have been described in the foregoing, these are merely for illustrative purposes and are not intended in any way to limit the scope of the invention.

### REFERENCE SIGNS LIST

| | | |
|---|---|---|
| 10: production apparatus, | 14: crucible, | 15: Si—C solution, |

| | | |
|---|---|---|
| 20B: drive source, | 22A: seed shaft, | 22C: drive source, |

| | |
|---|---|
| 24A, 24A1, 41 to 47: stirring member, | 32: SiC seed crystal |

1-10. (canceled)

11. A SiC single crystal production apparatus for use in a solution growth technique, the apparatus comprising:
a seed shaft having a lower end surface to which a SiC seed crystal is to be attached;
a crucible configured to contain a Si—C solution;
a stirring member configured to be immersed in the Si—C solution, the stirring member being arranged so that a lower end of the stirring member is located lower than a lower end of the SiC seed crystal that is to be attached to the lower end surface of the seed shaft; and
a drive source configured to cause relative rotation between the crucible and the stirring member.

12. The SiC single crystal production apparatus according to claim 11,
wherein the drive source includes a first drive source configured to cause the crucible to rotate.

13. The SiC single crystal production apparatus according to claim 12,
wherein the drive source further includes a second drive source configured to cause the stirring member to rotate about a central axis of the seed shaft.

14. The SiC single crystal production apparatus according to claim 13,
wherein the second drive source causes the stirring member to rotate in a direction opposite to the rotational direction of the crucible.

15. The SiC single crystal production apparatus according to claim 11,
wherein the stirring member is placed below the SiC seed crystal.

16. The SiC single crystal production apparatus according to claim 12,
wherein the stirring member is placed below the SiC seed crystal.

17. The SiC single crystal production apparatus according to claim 13,
wherein the stirring member is placed below the SiC seed crystal.

18. The SiC single crystal production apparatus according to claim 14,
wherein the stirring member is placed below the SiC seed crystal.

19. The SiC single crystal production apparatus according to claim 15,
wherein the stirring member is an impeller that is rotatable about the central axis of the seed shaft.

20. The SiC single crystal production apparatus according to claim 16,
wherein the stirring member is an impeller that is rotatable about the central axis of the seed shaft.

21. The SiC single crystal production apparatus according to claim 17,
wherein the stirring member is an impeller that is rotatable about the central axis of the seed shaft.

22. The SiC single crystal production apparatus according to claim 18,
wherein the stirring member is an impeller that is rotatable about the central axis of the seed shaft.

23. The SiC single crystal production apparatus according to claim 19,
wherein the impeller has blades that are oriented obliquely with respect to the central axis of the seed shaft, and the blades are rotatable about the central axis of the seed shaft.

24. The SiC single crystal production apparatus according to claim 20,
wherein the impeller has blades that are oriented obliquely with respect to the central axis of the seed shaft, and the blades are rotatable about the central axis of the seed shaft.

25. The SiC single crystal production apparatus according to claim 21,
wherein the impeller has blades that are oriented obliquely with respect to the central axis of the seed shaft, and the blades are rotatable about the central axis of the seed shaft.

26. The SiC single crystal production apparatus according to claim 22,
wherein the impeller has blades that are oriented obliquely with respect to the central axis of the seed shaft, and the blades are rotatable about the central axis of the seed shaft.

27. The SiC single crystal production apparatus according to claim 11,
wherein the stirring member is attached to the seed shaft and the drive source causes the seed shaft to rotate.

28. A method of producing a SiC single crystal by a solution growth technique, the method comprising the steps of:
preparing a production apparatus that includes a seed shaft having a lower end surface to which a SiC seed crystal is attached, a crucible configured to contain a Si—C solution, and a stirring member configured to be immersed in the Si—C solution;
forming a Si—C solution;
immersing the stirring member in the Si—C solution; and
bringing the SiC seed crystal into contact with the Si—C solution and growing the SiC single crystal,
wherein the step of growing a SiC single crystal includes causing relative rotation between the crucible and the stirring member, with a lower end of the stirring member being located lower than a lower end of the SiC seed crystal attached to the lower end surface of the seed shaft.

29. The method of producing a SiC single crystal according to claim 28,
wherein, in the step of growing a SiC single crystal, the stirring member is rotated in a direction opposite to the rotational direction of the crucible.
